(19) United States
(12) Patent Application Publication
(10) Pub. No.: US 2025/0203766 A1
(43) Pub. Date: Jun. 19, 2025

(54) PRINTED WIRING BOARD

(71) Applicant: IBIDEN CO., LTD., Ogaki (JP)

(72) Inventors: Jun SAKAI, Ibi-gun (JP); Kyohei YOSHIKAWA, Ogaki (JP)

(73) Assignee: IBIDEN CO., LTD., Ogaki (JP)

(21) Appl. No.: 18/983,923

(22) Filed: Dec. 17, 2024

(30) Foreign Application Priority Data
Dec. 18, 2023 (JP) 2023-212842

(51) Int. Cl. H05K 1/02; H05K 1/11; H05K 3/18

(52) U.S. Cl. CPC H05K 1/0298; H05K 1/115; H05K 3/18; H05K 2201/096; H05K 2201/10734

(57) ABSTRACT

A printed wiring board includes an uppermost conductor layer having an electrode that mounts an electronic component, an upper build-up part including conductor layers and resin insulating layers such that the uppermost conductor layer is formed on the upper build-up part, and a lower build-up part including conductor layers and resin insulating layers and formed such that the lower build-up part is formed below the upper build-up part. The upper build-up part is formed such that each of the conductor layers includes a seed layer formed by sputtering, and an electrolytic plating layer formed below the seed layer, and the lower build-up part is formed such that each of the conductor layers includes a seed layer formed by electroless plating, and an electrolytic plating layer formed below the seed layer.

### CROSS-REFERENCE TO RELATED APPLICATIONS

The present application is based upon and claims the benefit of priority to Japanese Patent Application No. 2023-212842, filed Dec. 18, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2000-124602 describes a method for manufacturing a printed wiring board. The entire contents of this publication are incorporated herein by reference.

### SUMMARY OF THE INVENTION

According to one aspect of the present invention, a printed wiring board includes an uppermost conductor layer having an electrode that mounts an electronic component, an upper build-up part including conductor layers and resin insulating layers such that the uppermost conductor layer is formed on the upper build-up part, and a lower build-up part including conductor layers and resin insulating layers and formed such that the lower build-up part is formed below the upper build-up part. The upper build-up part is formed such that each of the conductor layers includes a seed layer formed by sputtering, and an electrolytic plating layer formed below the seed layer, and the lower build-up part is formed such that each of the conductor layers includes a seed layer formed by electroless plating, and an electrolytic plating layer formed below the seed layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a portion of a printed wiring board according to an embodiment of the present invention;

FIG. 3 is an enlarged cross-sectional view schematically illustrating a part of a printed wiring board according to an embodiment of the present invention;

FIG. 4 is an enlarged cross-sectional view schematically illustrating a part of a printed wiring board according to an embodiment of the present invention; and

FIG. 5 is an enlarged cross-sectional view schematically illustrating a part of a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

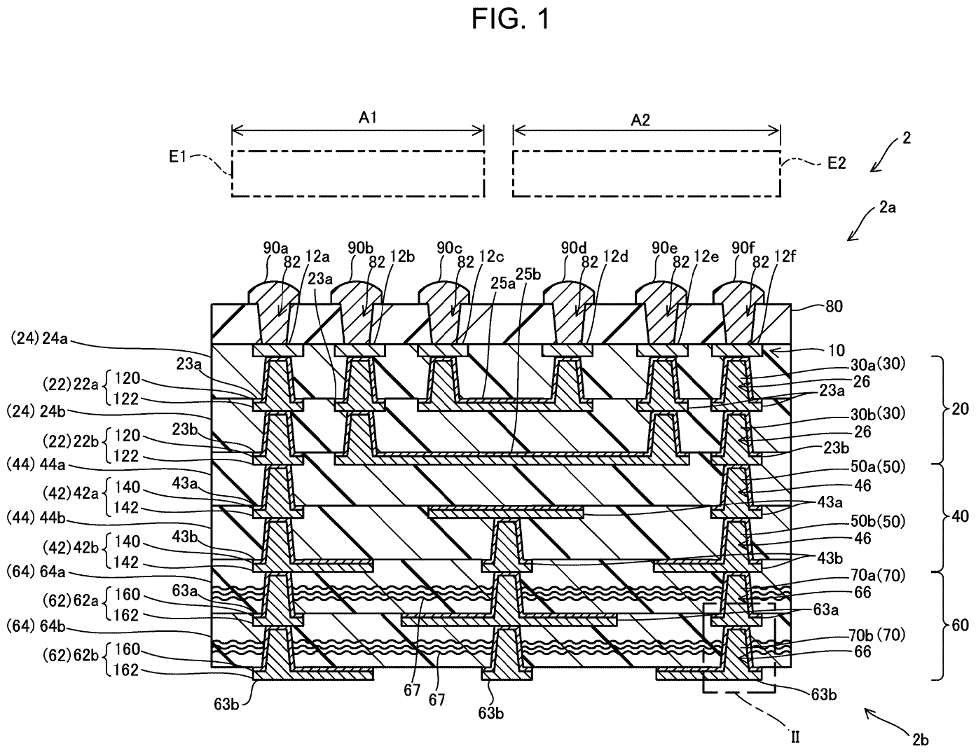

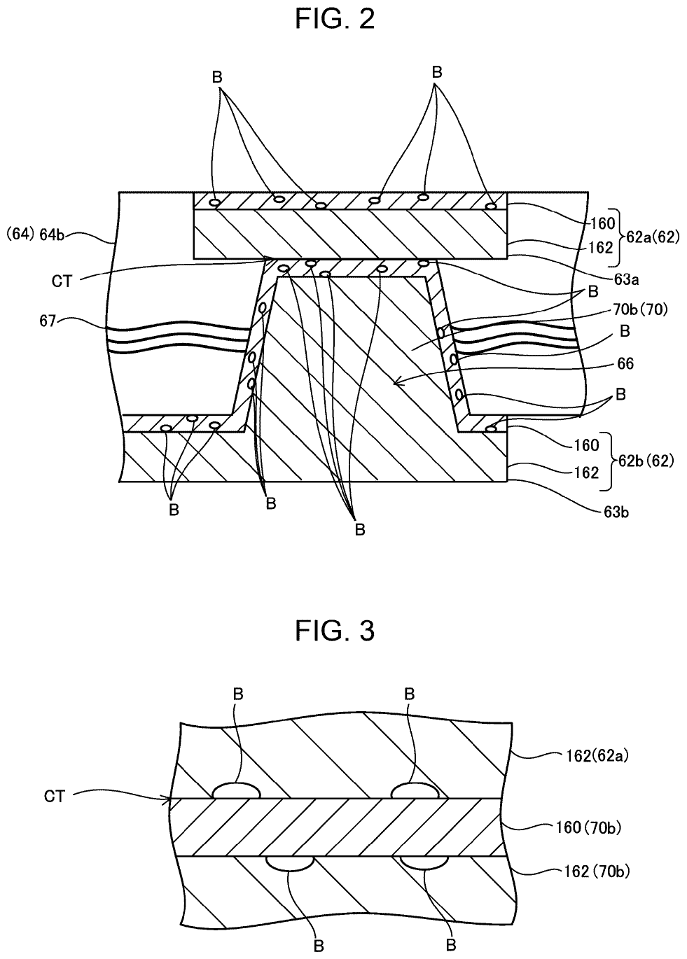

FIG. 1 is a cross-sectional view illustrating a printed wiring board 2 according to an embodiment of the present invention. FIGS. 2 and 3 are each an enlarged cross-sectional view illustrating a part of the printed wiring board 2 of the embodiment. As illustrated in FIG. 1, the printed wiring board 2 has an upper surface (2a) and a lower surface (2b) on an opposite side with respect to the upper surface (2a). The upper surface (2a) has a first mounting region (A1) for mounting a first electronic component (E1) and a second mounting region (A2) for mounting a second electronic component (E2). The first mounting region (A1) is positioned directly below the first electronic component (E1). The second mounting region (A2) is positioned directly below the second electronic component (E2). Examples of the first electronic component (E1) and the second electronic component (E2) are electronic components such as logic ICs and memories. Examples of logic ICs include microprocessors, digital signal processors (DSPs), and the like.

The printed wiring board 2 has a third build-up part 60, a second build-up part 40, a first build-up part 20, an uppermost conductor layer 10, a solder resist layer 80, and bumps (90a-90f). The printed wiring board 2 does not have a core substrate. The printed wiring board 2 is an asymmetric substrate. The first build-up part 20 is formed below the uppermost conductor layer 10. The first build-up part 20 is formed directly below the uppermost conductor layer 10. The second build-up part 40 is formed below the first build-up part 20. The third build-up part 60 is formed below the second build-up part 40. The solder resist layer 80 is formed on the uppermost conductor layer 10 and on the first build-up part 20. The bumps (90a-90f) are formed in openings 82 that penetrate the solder resist layer 80 and on the solder resist layer 80. Via the bumps (90a-90f), the first electronic component (E1) and the second electronic component (E2) are mounted on the printed wiring board 2. In the embodiment, the second build-up part 40 can be omitted. In this case, the printed wiring board is formed by the third build-up part 60, the first build-up part 20 on the third build-up part 60, the uppermost conductor layer 10 on the first build-up part 20, the solder resist layer 80 on the first build-up part 20 and the uppermost conductor layer 10, and the bumps (90a-90f).

The uppermost conductor layer 10 includes electrodes (12a-12f) for mounting the electronic components (E1, E2). The electrodes (12a-12c) are electrically connected to the first electronic component (E1). The electrodes (12d-12f) are electrically connected to the second electronic component (E2). The uppermost conductor layer 10 is mainly formed of copper. The bumps (90a-90f) are respectively formed on the electrodes (12a-12f). The bumps (90a-90f) are formed of solder or plating. The first electronic component (E1) and the second electronic component (E2) are mounted on the bumps (90a-90f). The first electronic component (E1) and the second electronic component (E2) are mounted on the electrodes (12a-12f) via the bumps (90a-90f).

The third build-up part 60 has multiple third conductor layers 62, multiple third resin insulating layers 64, and multiple third via conductors 70. The third conductor layers 62 and the third resin insulating layers 64 are alternately laminated. The third via conductors 70 are formed in third openings 66 that penetrate the third resin insulating layers 64. Adjacent third conductor layers 62 are connected by the third via conductors 70. In FIG. 1, the number of the third conductor layers 62 and the number of the third resin insulating layers 64 are two. It is also possible that the number of the third conductor layers 62 and the number of the third resin insulating layers 64 are three or more.

The third conductor layers 62 are mainly formed of copper. The third conductor layers 62 are each formed of a third seed layer 160 and a third electrolytic plating layer 162 below the third seed layer 160. The third seed layer 160 is formed by electroless plating. An example of electroless plating is electroless copper plating. The third conductor layers 62 include an upper third conductor layer (62a) and a lower third conductor layer (62b). The upper third conductor layer (62a) and the lower third conductor layer (62b) sandwich one third resin insulating layer 64. The upper third conductor layer (62a) is closer to the uppermost conductor layer 10 than the lower third conductor layer (62b) is. The upper third conductor layer (62a) has pads (63a). The lower third conductor layer (62b) has pads (63b).

The third resin insulating layers 64 are formed using a thermosetting resin. An example of a thermosetting resin is an epoxy resin. The third resin insulating layers 64 may contain inorganic particles such as silica particles. The third resin insulating layers 64 include an upper third resin insulating layer (64a) and a lower third resin insulating layer (64b). The lower third resin insulating layer (64b) is a lowermost resin insulating layer. The third resin insulating layers 64 each contain a fibrous reinforcing material 67. An example of a fibrous reinforcing material 67 is glass cloth or the like.

As illustrated in FIGS. 1 and 2, the third via conductors 70 are formed in the third openings 66. FIG. 2 is an enlarged view of a portion indicated by “II” in FIG. 1. The third via conductors 70 include upper third via conductors (70a) and lower third via conductors (70b). The lower third via conductors (70b) connect the upper third conductor layer (62a) and the lower third conductor layer (62b). The upper third via conductors (70a) connect the upper third conductor layer (62a) and a second conductor layer 42 (lower second conductor layer (42b)) in the second build-up part 40. The third via conductors 70 are each formed of a third seed layer 160 and a third electrolytic plating layer 162 below the third seed layer 160. The third seed layer 160 forming the third via conductors 70 and the third seed layer 160 forming the third conductor layers 62 are common. The third seed layer 160 forming the third via conductors 70 and the third seed layer 160 forming the third conductor layers 62 are formed at the same time. The third electrolytic plating layer 162 forming the third via conductors 70 and the third electrolytic plating layer 162 forming the third conductor layers 62 are common. The third electrolytic plating layer 162 forming the third via conductors 70 and the third electrolytic plating layer 162 forming the third conductor layers 62 are formed at the same time.

FIG. 2 illustrates two third conductor layers 62 in the third build-up part 60, one third opening 66 exposing one third conductor layer 62 (62a) among the two third conductor layers 62, and one third via conductor 70 (70b) formed in the one third opening 66. The third opening 66 in FIG. 2 penetrates one third resin insulating layer 64 (64b) and reaches the third conductor layer (62a). FIG. 3 is an enlarged view of a portion of FIG. 2. FIG. 3 illustrates a connection portion (CT) between the third via conductor (70b) and the third conductor layer (62a). The third conductor layer 62 exposed by the third opening 66 is connected to the third via conductor 70 filling the third opening 66 via the connection portion (CT). In FIGS. 2 and 3, the lower third via conductor (70b) is depicted as a representative example of the third via conductors 70, and the upper third conductor layer (62a) and the lower third conductor layer (62b) are depicted as representative examples of the third conductor layers 62. As illustrated in FIGS. 2 and 3, the third conductor layers 62 and the third via conductors 70 have voids (B). The voids (B) are present in at least one of a first location, a second location, and a third location. The first location is located in a seed layer formed of an electroless plating layer. An example of a seed layer formed of an electroless plating layer is the third seed layer 160. The second location is a boundary portion between a seed layer, which is formed of an electroless plating layer, and an electrolytic plating layer. An example of the second location is a boundary portion between the third seed layer 160 and the third electrolytic plating layer 162. The second location can include a second location in a conductor layer and a second location in a via conductor. The second location in a conductor layer is formed at an interface between an electrolytic plating layer forming the conductor layer and a seed layer formed of an electroless plating layer forming the conductor layer. An interface between an electrolytic plating layer and a seed layer formed of an electroless plating layer in one conductor layer is an example of a second location in a conductor layer. An example of a second location in a conductor layer is an interface between the third electrolytic plating layer 162 forming a third conductor layer 62 and the third seed layer 160 forming the third conductor layer 62. A second location in a via conductor is formed at an interface between an electrolytic plating layer forming the via conductor and a seed layer formed of an electroless plating layer forming the via conductor. An interface between an electrolytic plating layer and a seed layer formed of an electroless plating layer in one via conductor is an example of a second location in a via conductor. An example of a second location in a via conductor is an interface between the third electrolytic plating layer 162 forming a third via conductor 70 and the third seed layer 160 forming the third via conductor 70. The third location includes a connection portion (CT) between a conductor layer and a via conductor including a seed layer formed of an electroless plating layer. The connection portion (CT) is illustrated in FIGS. 2 and 3. The third location includes an interface between a conductor layer exposed by an opening (opening for a via conductor) and the via conductor formed in the opening (opening for a via conductor). The third location includes a boundary portion between a pad included in a conductor layer and a via conductor including a seed layer formed of an electroless plating layer. The third location includes a boundary portion between a pad included in a conductor layer and a seed layer formed of an electroless plating layer that forms a via conductor. A boundary portion between the third seed layer 160 that forms a third via conductor 70 and a pad (63a) is an example of the third location. The voids (B) are present in the first location. In this case, the voids (B) are preferably not present in the second location and the third location. Or, the voids (B) are present in the second location. In this case, the voids (B) are preferably not present in the first location and the third location. Or, the voids (B) are present in the third location. In this case, the voids (B) are preferably not present in the first location and the second location. Or, the voids (B) are present in the first location and the second location. In this case, the voids (B) are preferably not present in the third location. Or, the voids (B) are present in the first location and the third location. In this case, the voids (B) are preferably not present in the second location. Or, the voids (B) are present in the second location and the third location. In this case, the voids (B) are preferably not present in the first location. Or, the voids (B) are present in the first location, the second location, and the third location.

The upper third conductor layer (62a), the upper third via conductors (70a), the lower third conductor layer (62b), and the lower third via conductors (70b) preferably have voids (B).

As illustrated in FIG. 1, the second build-up part 40 has multiple second conductor layers 42, multiple second resin insulating layers 44, and multiple second via conductors 50. The second conductor layers 42 and the second resin insulating layers 44 are alternately laminated. The second via conductors 50 are formed in second openings 46 that penetrate the second resin insulating layers 44. Adjacent second conductor layers 42 are connected by the second via conductors 50. In FIG. 1, the number of the second conductor layers 42 and the number of the second resin insulating layers 44 are two. It is also possible that the number of the second conductor layers 42 and the number of the second resin insulating layers 44 are three or more.

The second conductor layers 42 are mainly formed of copper. The second conductor layers 42 are each formed of a second seed layer 140 and a second electrolytic plating layer 142 below the second seed layer 140. The second seed layer 140 is formed by electroless plating. The second conductor layers 42 include an upper second conductor layer (42a) and a lower second conductor layer (42b). The upper second conductor layer (42a) has pads (43a). The lower second conductor layer (42b) has pads (43b). The lower second conductor layer (42b) can also serve as a lowermost second conductor layer in the second build-up part 40.

The second resin insulating layers 44 are formed using a thermosetting resin. An example of a thermosetting resin is an epoxy resin. The second resin insulating layers 44 may contain inorganic particles such as silica particles. The second resin insulating layers 44 include an upper second resin insulating layer (44a) and a lower second resin insulating layer (44b). The second resin insulating layers 44 do not each contain a fibrous reinforcing material. The lower second resin insulating layer (44b) may also serve as a lowermost second resin insulating layer in the second build-up part 40.

The second via conductors 50 are formed in the second openings 46. The second via conductors 50 include upper second via conductors (50a) and lower second via conductors (50b). The lower second via conductors (50b) connect the upper second conductor layer (42a) and the lower second conductor layer (42b). The upper second via conductors (50a) connect the upper second conductor layer (42a) and a first conductor layer 22 (a lower first conductor layer (22b)) in the first build-up part 20. The second via conductors 50 are each formed of a second seed layer 140 and a second electrolytic plating layer 142 below the second seed layer 140. The second seed layer 140 forming the second via conductors 50 and the second seed layer 140 forming the second conductor layers 42 are common. The second seed layer 140 forming the second via conductors 50 and the second seed layer 140 forming the second conductor layers 42 are formed at the same time. The second electrolytic plating layer 142 forming the second via conductors 50 and the second electrolytic plating layer 142 forming the second conductor layers 42 are common. The second electrolytic plating layer 142 forming the second via conductors 50 and the second electrolytic plating layer 142 forming the second conductor layers 42 are formed at the same time.

The second conductor layers 42 have voids (B) similar to those in the third conductor layers 62. The second conductor layers 42 have voids (B) in similar locations to those in the third conductor layers 62. The second via conductors 50 have voids (B) similar to those in the third via conductors 70. The second via conductors 50 have voids (B) in similar locations to those in the third via conductors 70.

The first build-up part 20 has multiple first conductor layers 22, multiple first resin insulating layers 24, and multiple first via conductors 30. The first conductor layers 22 and the first resin insulating layers 24 are alternately laminated. The first via conductors 30 are formed in first openings 26 that penetrate the first resin insulating layers 24. Adjacent first conductor layers 22 are connected by the first via conductors 30. In FIG. 1, the number of the first conductor layers 22 and the number of the first resin insulating layers 24 are two. It is also possible that the number of the first conductor layers 22 and the number of the first resin insulating layers 24 are three or more.

The first conductor layers 22 are mainly formed of copper. The first conductor layers 22 are each formed of a first seed layer 120 and a first electrolytic plating layer 122 below the first seed layer 120. The first seed layer 120 is formed by sputtering. The first conductor layers 22 include an upper first conductor layer (22a) and a lower first conductor layer (22b). The upper first conductor layer (22a) has pads (23a) and connection wirings (25a). The lower first conductor layer (22b) has pads (23b) and connection wirings (25b).

The first resin insulating layers 24 are formed using a thermosetting resin. An example of a thermosetting resin is an epoxy resin. The first resin insulating layers 24 may contain inorganic particles such as silica particles. The first resin insulating layers 24 include an upper first resin insulating layer (24a) and a lower first resin insulating layer (24b). The upper first resin insulating layer (24a) is an uppermost resin insulating layer that is in contact with the uppermost conductor layer 10. The first resin insulating layers 24 do not each contain a fibrous reinforcement material.

The first via conductors 30 are formed in the first openings 26. The first via conductors 30 include upper first via conductors (30a) and lower first via conductors (30b). The lower first via conductors (30b) connect the upper first conductor layer (22a) and the lower first conductor layer (22b). The upper first via conductors (30a) connect the upper first conductor layer (22a) and the electrodes (12a-12f) in the uppermost conductor layer 10. The first via conductors 30 are each formed of a first seed layer 120 and a first electrolytic plating layer 122 below the first seed layer 120. The first seed layer 120 forming the first via conductors 30 and the first seed layer 120 forming the first conductor layers 22 are common. The first seed layer 120 forming the first via conductors 30 and the first seed layer 120 forming the first conductor layers 22 are formed at the same time. The first electrolytic plating layer 122 forming the first via conductors 30 and the first electrolytic plating layer 122 forming the first conductor layers 22 are common. The first electrolytic plating layer 122 forming the first via conductors 30 and the first electrolytic plating layer 122 forming the first conductor layers 22 are formed at the same time.

The first conductor layers 22 and the first via conductors 30 do not have voids. The first conductor layers 22 are each formed of the first seed layer 120 and the first electrolytic plating layer 122 below the first seed layer 120. The first seed layer 120 is formed by sputtering, and the first electrolytic plating layer 122 is formed by electrolytic plating. Voids are not present at a boundary portion between the first seed layer (first layer) 120 forming the first conductor layers 22 and the first electrolytic plating layer (second layer) 122 forming the first conductor layers 22. The first layer and the second layer are in contact with each other. Voids are not present in the first seed layer 120 formed by sputtering. Voids are not present at a boundary portion between the first via conductors 30 and the pads (23a). Voids are not present at a boundary portion between the first seed layer 120, which forms the first via conductors 30, and the pads (23a). The pads (23a) are one of conductor circuits that form the first conductor layers 22. The first openings 26 penetrate the first resin insulating layers 24 to reach the pads (23a). Voids are not present in at a boundary portion between the first seed layer 120, which forms the first via conductors 30, and the uppermost conductor layer 10. Voids are not present at a boundary portion between the first seed layer 120, which forms the first via conductors 30, and the electrodes (12a-12f). The first openings 26 penetrate the uppermost resin insulating layer (24a) to reach the uppermost conductor layer 10, which includes the electrodes (12a-12f). The first via conductors 30 fill the first openings 26. Voids are not present at a boundary portion between the first seed layer (third layer) 120 forming the first via conductors 30 and the first electroplated layer (fourth layer) 122 forming the first via conductors 30. The third layer and the fourth layer are in contact with each other.

The first build-up part 20 has the multiple first conductor layers 22. Some of the multiple first conductor layers 22 have connection wirings (25a, 25b). Among the multiple first conductor layers 22, half or more of the first conductor layers 22 can have connection wirings (25a, 25b). For example, the number of the first conductor layers 22 having connection wirings (25a, 25b) is 3 or more and 7 or less. As illustrated in FIG. 1, all the first conductor layers 22 may have connection wirings (25a, 25b). Data is transmitted from the first electronic component (E1) to the second electronic component (E2) via the connection wirings (25a, 25b). The connection wirings (25a, 25b) are a part of a path for transmitting data from the first electronic component (E1) to the second electronic component (E2). The path includes the first via conductors 30 in addition to the connection wirings (25a, 25b). Since the connection wirings (25a, 25b) and the first via conductors 30 that form the path do not contain voids (B), the path can transmit high-speed data. Further, when data is transmitted via the path, the printed wiring board 2 of the embodiment can reduce transmission loss.

In the embodiment, the first seed layer 120 of the first conductor layers 22 that have the connection wirings (25a, 25b) is formed by sputtering. The second seed layer 140 of the second conductor layers 42 that do not have connection wirings is formed by electroless plating. The third seed layer 160 of the third conductor layers 62 that do not have connection wirings is formed by electroless plating.

The first build-up part 20 has the connection wirings that include a seed layer formed by sputtering and the resin insulating layers that do not contain a fabrous reinforcing material. The second build-up part 40 has the conductor layers that include a seed layer formed by electroless plating and the resin insulating layers that do not contain a fibrous reinforcing material. The second build-up part 40 has no connection wirings. The third build-up part 60 has the conductor layers that include a seed layer formed by electroless plating and the resin insulating layers that contain a fibrous reinforcing material. The third build-up part 60 has no connection wirings.

A thickness of each of the third resin insulating layers 64 is greater than a thickness of each of the second resin insulating layers 44. The thickness of each of the second resin insulating layers 44 is greater than a thickness of each of the first resin insulating layers 24. The thickness of each of the third resin insulating layers 64 is, for example, 90 μm or more and 110 μm or less. The thickness of each of the second resin insulating layers 44 is, for example, 20 μm or more and 25 μm or less. The thickness of each of the first resin insulating layers 24 is, for example, 8 μm or more and 12 μm or less. The thickness of each of the third resin insulating layers 64 is substantially the same as a distance between the third conductor layers 62 that sandwich one third resin insulating layer 64. The thickness of each of the second resin insulating layers 44 is substantially the same as a distance between the second conductor layers 42 that sandwich one second resin insulating layer 44. The thickness of each of the first resin insulating layers 24 is substantially the same as a distance between the first conductor layers 22 that sandwich one first resin insulating layer 24.

A thickness of each of the third conductor layers 62 is greater than a thickness of each of the second conductor layers 42. The thickness of each of the second conductor layers 42 is greater than a thickness of each of the first conductor layers 22. The thickness of each of the third conductor layers 62 is, for example, 10 μm or more and 30 μm or less. The thickness of each of the second conductor layers 42 is, for example, 13 μm or more and 17 μm or less. The thickness of each of the first conductor layers 22 is, for example, 3 μm or more and 7 μm or less. The thickness of each of the third conductor layers 62 is measured using the third conductor layer 62 sandwiched between the third resin insulating layers 64. The thickness of each of the second conductor layers 42 is measured using the second conductor layer 42 sandwiched between the second resin insulating layers 44. The thickness of each of the first conductor layers 22 is measured using the first conductor layer 22 sandwiched between the first resin insulating layers 24.

The printed wiring board 2 has a thickness of 0.5 mm or more and 0.7 mm or less. A length of a short side of the printed wiring board 2 is 70 mm or more, and a length of a long side of the printed wiring board 2 is 250 mm or less.

A seed layer forming a conductor layer that has connection wirings is formed by sputtering. A seed layer forming a conductor layer that does have connection wirings is formed by electroless plating. A seed layer of a conductor layer that has connection wirings is a sputtered seed layer, and a seed layer of a conductor layer that does not have connection wirings is an electroless plated seed layer. An example of a seed layer formed by electroless plating (electroless plated seed layer) is an electroless copper plated seed layer.

For example, a seed layer in contact with a resin insulating layer that does not contain a fibrous reinforcing material is formed by sputtering. A seed layer formed by sputtering (sputtered seed layer) preferably contains copper and aluminum. A sputtered seed layer may contain copper, aluminum, and silicon. For example, a seed layer in contact with a resin insulating layer that contains a fibrous reinforcing material is formed by electroless plating. An example of electroless plating is electroless copper plating. For example, a seed layer in contact with a resin insulating layer that does not contain a fibrous reinforcing material is a sputtered seed layer, and a seed layer in contact with a resin insulating layer that contains a fibrous reinforcing material is an electroless plated seed layer.

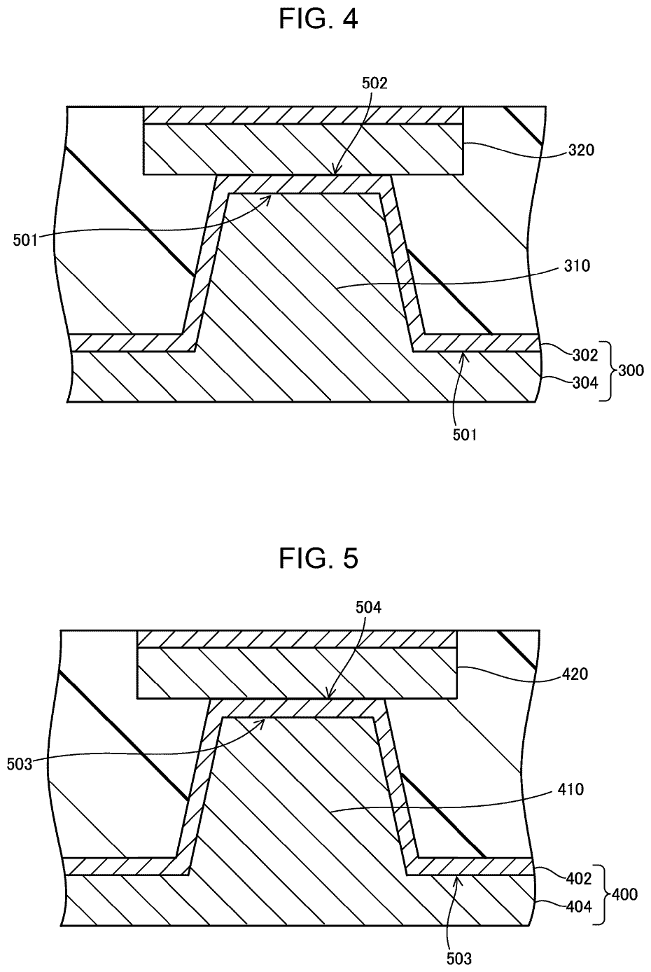

Voids are preferably present in an electroless plated seed layer. A conductor layer that includes an electroless plated seed layer (electroless plated conductor layer) preferably has voids at a boundary portion between the electroless plated seed layer that forms the electroless plated conductor layer and the electrolytic plating layer that forms the electroless plated conductor layer. A via conductor including an electroless plated seed layer (electroless plated via conductor) preferably has voids at a boundary portion between the electroless plated seed layer that forms the electroless plated via conductor and the electrolytic plating layer that forms the electroless plated via conductor. Voids are preferably present at a boundary between the electroless plated seed layer of the electroless plated via conductor and the pad. As illustrated in FIG. 4, a boundary portion between an electroless plated seed layer 302 and an electrolytic plating layer 304 in an electroless plated conductor layer 300 is a first boundary portion 501. A boundary portion between an electroless plated seed layer 302 and an electrolytic plating layer 304 in an electroless plated via conductor 310 is a first boundary portion 501. A boundary portion between the electroless plated seed layer 302 in the electroless plated via conductor 310 and a pad 320 is a second boundary portion 502.

The first boundary portions 501 are included in second locations. The first boundary portions 501 can include a second location in a conductor layer and a second location in a via conductor. An example of a second location in a conductor layer is a second location in a third conductor layer. An example of a second location in a via conductor is a second location in a third via conductor. A conductor layer having a second location in a conductor layer includes an electroless plated seed layer. A via conductor having a second location in a via conductor includes an electroless plated seed layer. The second boundary portion 502 is included in a third location. A via conductor forming a second boundary portion 502 includes an electroless plated seed layer.

Voids are preferably not present in a sputtered seed layer. A conductor layer that includes a sputtered seed layer (sputtered conductor layer) preferably does not have voids at a boundary portion between the sputtered seed layer that forms the sputtered conductor layer and the electrolytic plating layer that forms the sputtered conductor layer. A via conductor that includes a sputtered seed layer (sputtered via conductor) preferably does not have voids at a boundary portion between the sputtered seed layer that forms the sputtered via conductor and the electrolytic plating layer that forms the sputtered via conductor. Voids are preferably not present in a boundary portion between the sputtered seed layer of a sputtered via conductor and a pad. Voids are preferably not present in a boundary portion between the sputtered seed layer of a sputtered via conductor and an electrode. As illustrated in FIG. 5, a boundary portion between a sputtered seed layer 402 and an electrolytic plating layer 404 in a sputtered conductor layer 400 is a third boundary portion 503. A boundary portion between a sputtered seed layer 402 and an electrolytic plating layer 404 in a sputtered via conductor 410 is a third boundary portion 503. A boundary portion between a sputtered seed layer 402 of a sputtered via conductor 410 and a pad 420 is a fourth boundary portion 504. A boundary portion between a sputtered seed layer 402 of a sputtered via conductor 410 and an electrode (12a-12f) is a fourth boundary portion 504.

The printed wiring board 2 of the embodiment is formed of a lowermost build-up part having a lowermost conductor layer, an uppermost build-up part formed on the lowermost build-up part, and an uppermost conductor layer formed on the uppermost build-up part. A conductor layer forming the lowermost build-up part includes an electroless plated seed layer and does not include connection wirings. A conductor layer forming the uppermost build-up part includes a sputtered seed layer and includes connection wirings. A resin insulating layer forming the lowermost build-up part includes a fibrous reinforcing material, and a resin insulating layer forming the uppermost build-up part does not include a fibrous reinforcing material. An example of the uppermost build-up part is the first build-up part 20, and an example of the lowermost build-up part is the third build-up part 60.

### Method for Manufacturing Printed Wiring Board

The uppermost conductor layer 10 is formed on a support plate. The first build-up part 20 is formed on the support plate and the uppermost conductor layer 10. The first seed layer 120 of the first conductor layers 22 is formed by sputtering. The first conductor layers 22 and the first via conductors 30 do not have voids. The second build-up part 40 is formed on the first build-up part 20. The second seed layer 140 of the second conductor layers 42 is formed by electroless plating. When the second seed layer 140 is formed by electroless plating, for example, a gas (for example, a hydrogen gas) generated during an electroless plating process is introduced into an intermediate substrate. After the second seed layer 140 is formed, heat is applied to the intermediate substrate. By adjusting a heating condition, voids (B) are formed in at least one of the first, second, and third locations in the second build-up part 40. The third build-up part 60 is formed on the second build-up part 40. The third seed layer 160 of the third conductor layers 62 is formed by electroless plating. The third seed layer 160 is formed using the same method as the second seed layer 140. Voids (B) are formed in at least one of the first, second, and third locations in the third build-up part 60. The support plate is removed. The uppermost resin insulating layer (24a) belongs to the first resin insulating layers 24 and is positioned directly below the uppermost conductor layer 10. The uppermost resin insulating layer (24a) is in contact with the uppermost conductor layer 10. The intermediate substrate is formed such that the uppermost conductor layer 10 and the uppermost resin insulating layer (24a) face up. The solder resist layer 80 and bumps (90a-90f) are formed on the uppermost conductor layer 10 and the uppermost resin insulating layer (24a). The printed wiring board 2 is obtained. An example of electrolytic plating is electrolytic copper plating, and an example of an electrolytic plating layer is an electrolytic copper plating layer. An example of electroless plating is electroless copper plating.

In the embodiment, not all the seed layers of the conductor layers are formed by sputtering. Therefore, even when a production process includes sputtering, the embodiment can increase productivity. The embodiment can suppress production costs.

Electroless plating and sputtering are different in principle. Therefore, it is difficult to make adhesion strength (first adhesion strength) between an electroless plated seed layer and an electrolytic plating layer on the electroless plated seed layer the same as adhesion strength (second adhesion strength) between a sputtered seed layer and an electrolytic plating layer on the sputtered seed layer. It is difficult to make adhesion strength (third adhesion strength) between a pad and an electroless plated seed layer on the pad the same as adhesion strength (fourth adhesion strength) between a pad and a sputtered seed layer on the pad. When the printed wiring board is used, the printed wiring board is subjected to stress repeatedly. When the second adhesion strength is lower than the first adhesion strength, stress is likely to concentrate at a boundary portion between the sputtered seed layer and the electrolytic plating layer. Or, stress is likely to concentrate in the sputtered seed layer. When the fourth adhesion strength is lower than the third adhesion strength, stress is likely to concentrate at a boundary portion between the pad and the sputtered seed layer. Stress is also likely to concentrate at a boundary portion between the electrode and the sputtered seed layer. Therefore, due to stress, the following problems are likely to occur. For example, peeling occurs between the sputtered seed layer and the electrolytic plating layer. Or, peeling occurs between the pad and the sputtered seed layer. Or, connection resistance between the pad and the via conductor that includes the sputtered seed layer increases. Or, connection resistance between the electrode and the via conductor that includes the sputtered seed layer increases. Or, a crack occurs in the sputtered seed layer.

An electroless plated seed layer is formed in liquid. Therefore, even when a surface to be plated has unevenness, an electroless plated seed layer easily follows the unevenness. Further, even when the surface to be plated has large recesses, an electroless plating layer is likely to be formed in the large recesses. In contrast, in sputtering, particles ejected from a target. These particles are likely to travel straight. Therefore, when a surface to be sputtered has unevenness, it is thought that variation in thickness of a sputtered seed layer is larger. Further, when a surface to be sputtered has a large recess, a sputtered seed layer is unlikely to grow on walls or bottom of the large recess. A sputtered seed layer is formed on the surface to be sputtered. However, in the embodiment, a conductor layer that includes a seed layer formed by electroless plating (for example, the third seed layer 160) has voids (B) in at least one of the first location and the second location. A via conductor that includes a seed layer formed by electroless plating has voids (B) in at least one of the first location, the second location, and the third location. In contrast, a conductor layer that includes a sputtered seed layer (for example, the first seed layer 120) does not have voids (B) in the first location and the second location. A via conductor that includes a sputtered seed layer does not have voids (B) in the first location, the second location, and the third location. Therefore, substantially the same stress is likely to act on the first boundary portion 501 and the third boundary portion 503. Substantially the same stress is likely to act on the second boundary portion 502 and the fourth boundary portion 504. Substantially the same stress is likely to act on the first boundary portion 501, the second boundary portion 502, the third boundary portion 503, and the fourth boundary portion 504. Even when the printed wiring board 2 of the embodiment is subjected to stress repeatedly, peeling is unlikely to occur between a seed layer and an electrolytic plating layer. Peeling is unlikely to occur between a pad and a via conductor. Peeling is unlikely to occur between an electrode and a via conductor. A crack is unlikely to occur in a seed layer. Connection resistance between a pad and a via conductor remains stable over a long period. Connection resistance between an electrode and a via conductor remains stable over a long period. A printed wiring board 2 with high connection reliability is provided.

The resin insulating layers 64 that form the third build-up part 60 each contain a fibrous reinforcement material 67, whereas the resin insulating layers 24 that form the first build-up part 20 do not each contain a fibrous reinforcement material 67. The printed wiring board 2 of the embodiment is an asymmetric wiring substrate. Therefore, the printed wiring board 2 of the embodiment is likely to have significant warpage. The electronic components (E1, E2) are mounted on the first build-up part 20. When the electronic components (E1, E2) are mounted on the first build-up part 20, the printed wiring board 2 of the embodiment and the electronic components (E1, E2) form a semiconductor device. When the semiconductor device is subjected to heat cycles, the third build-up part 60 is likely to have greater warpage than the first build-up part 20. Since the third build-up part 60 is farther from the electronic components (E1, E2) than the first build-up part 20, it is thought that the third build-up part 60 is likely to have greater warpage. However, the conductor layers (third conductor layers) 62 and/or the via conductors (third via conductors) 70 in the third build-up part 60 have voids (B) in at least one of the first location, the second location, and the third location. The stress is relaxed by the voids (B). Therefore, even when the semiconductor device is subjected to heat cycles, the embodiment can provide a printed wiring board 2 with high connection reliability. When the conductor layers (first conductor layers) 22 and the via conductors (first via conductors) 30 in the first build-up part 20 have voids (B), since the first build-up part 20 is close to the electronic components (E1, E2), the voids (B) in the first build-up part 20 expand due to heat generated by the electronic components (E1, E2). In this case, connection reliability via the wirings in the first build-up part 20 decreases. The wirings in the first build-up part 20 include the first conductor layers 22 and the first via conductors 30. Since the conductor layers 22 and via conductors 30 in the first build-up part 20 of the printed wiring board 2 of the embodiment do not have voids (B), such issues are unlikely to occur.

### Alternative Example

In an alternative example, the second conductor layers 42 and the second via conductors 50 do not have voids. The second seed layer 140 is formed by sputtering. The voids (B) are not present at a boundary portion between the second seed layer 140 formed by sputtering and the second electrolytic plating layer 142 formed by electrolytic plating. The second conductor layers 42 are formed by the second seed layer 140 formed by sputtering and the second electrolytic plating layer 142 formed by electrolytic plating. The second via conductors 50 are formed by the second seed layer 140 formed by sputtering and the second electrolytic plating layer 142 formed by electrolytic plating. Voids are not present in the second seed layer 140 formed by sputtering. Voids are not present at a boundary portion between the second via conductors (50b) and the pads (43a).

The terms “upper” and “lower” are used based on FIG. 1. A conductor layer formed of a seed layer and an electrolytic plating layer on the seed layer and a conductor layer formed of a seed layer and an electrolytic plating layer below the seed layer are similar conductor layers. A via conductor formed of a seed layer and an electrolytic plating layer on the seed layer and a via conductor formed of a seed layer and an electrolytic plating layer below the seed layer are similar via conductors.

Japanese Patent Application Laid-Open Publication No. 2000-124602 describes a method for manufacturing a printed wiring board, which includes forming an opening for via hole formation in an interlayer resin insulating layer and forming an alloy layer by sputtering on a surface of the interlayer insulating layer having the opening for via hole formation.

Sputtering is performed in vacuum. It is thought that, when a printed wiring board including multiple conductor layers is formed, forming seed layers of all the conductor layers by sputtering affects productivity. It is thought that production cost increases.

A printed wiring board according to an embodiment of the present invention includes: an uppermost conductor layer having an electrode for mounting an electronic component; a first build-up part formed below the uppermost conductor layer; and a third build-up part formed below the first build-up part. The first build-up part has multiple first conductor layers and multiple first resin insulating layers, the first conductor layers and the first resin insulating layers being alternately laminated. The third build-up part has multiple third conductor layers and multiple third resin insulating layers, the third conductor layers and the third resin insulating layers being alternately laminated. The first conductor layers are each formed of a first seed layer, which is formed by sputtering, and a first electrolytic plating layer formed below the first seed layer. The third conductor layers are each formed of a third seed layer, which is formed by electroless plating, and a third electrolytic plating layer formed below the third seed layer.

A printed wiring board according to an embodiment of the present invention has the first conductor layers that each include the first seed layer formed by sputtering, and the third conductor layers that each include the third seed layer formed by electroless plating. Therefore, not all the seed layers of the conductor layers are formed by sputtering. Therefore, productivity of the printed wiring board is unlikely to decrease. The embodiment can suppress production costs.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an uppermost conductor layer having an electrode configured to mount an electronic component;
an upper build-up part comprising a plurality of conductor layers and a plurality of resin insulating layers such that the uppermost conductor layer is formed on the upper build-up part; and
a lower build-up part comprising a plurality of conductor layers and a plurality of resin insulating layers and formed such that the lower build-up part is formed below the upper build-up part,
wherein the upper build-up part is formed such that each of the conductor layers comprises a seed layer formed by sputtering, and an electrolytic plating layer formed below the seed layer, and the lower build-up part is formed such that each of the conductor layers comprises a seed layer formed by electroless plating, and an electrolytic plating layer formed below the seed layer.

2. The printed wiring board according to claim 1, wherein the lower build-up part is formed such that each of the conductor layers has voids in the seed layer and/or at a boundary portion between the seed layer and the electrolytic plating layer, and the upper build-up part is formed such that each of the conductor layers do not have voids in the seed layer and at a boundary portion between the seed layer and the electrolytic plating layer.

3. The printed wiring board according to claim 2, wherein the lower build-up part is formed such that each of the conductor layers has the voids in the seed layer and at the boundary portion between the seed layer and the electrolytic plating layer.

4. The printed wiring board according to claim 1, wherein the lower build-up part is formed such that the plurality of conductor layers includes an upper conductor layer and a lower conductor layer and that one of the resin insulating layers is formed between the upper conductor layer and the lower conductor layer, the lower build-up part includes a via conductor formed in the one of the resin insulating layers and comprising the seed layer and electrolytic plating layer of the upper conductor layer such that the via conductor is connected to a pad formed in the upper conductor layer and that a connection portion between the pad and the via conductor has voids in the seed layer of the upper conductor layer and/or at a boundary portion between the seed layer and the electrolytic plating layer in the upper conductor layer, and the upper build-up part is formed such that each of the conductor layers does not have voids in the seed layer and at a boundary portion between the seed layer and the electrolytic plating layer.

5. The printed wiring board according to claim 4, wherein the lower build-up part is formed such that the via conductor has the voids in the seed layer of the upper conductor layer and at the boundary portion between the seed layer and the electrolytic plating layer in the upper conductor layer.

6. The printed wiring board according to claim 1, further comprising:
a second build-up part comprising a plurality of resin insulating layers and a plurality of conductor layers and formed between the upper build-up part forming a first build-up part and the lower build-up part forming a third build-up part,
wherein the second build-up part is formed such that each of the conductor layers comprises a seed layer formed by electroless plating and an electrolytic plating layer formed below the seed layer and has voids in the seed layer and/or at a boundary portion between the seed layer and the electrolytic plating layer.

7. The printed wiring board according to claim 1, wherein the lower build-up part is formed such that each of the resin insulating layers includes reinforcing material, and the upper build-up part is formed such that each of the first resin insulating layer does not contain reinforcing material.

8. The printed wiring board according to claim 1, wherein the lower build-up part is formed such that a thickness of each of the resin insulating layers is greater than a thickness of each of the resin insulating layers in the upper build-up part and that a thickness of each of the conductor layers is greater than a thickness of each of the conductor layers in the upper build-up part.

9. The printed wiring board according to claim 1, wherein the upper build-up part is formed such that the plurality of resin insulating layers includes an uppermost resin insulating layer formed in contact with the uppermost conductor layer, and the lower build-up part is formed such that the plurality of resin insulating layers includes a lowermost resin insulating layer.

10. The printed wiring board according to claim 1, further comprising:
a bump formed on the electrode in the uppermost conductor layer.

11. The printed wiring board according to claim 10, wherein the bump comprises solder or plating.

12. The printed wiring board according to claim 2, further comprising:
a second build-up part comprising a plurality of resin insulating layers and a plurality of conductor layers and formed between the upper build-up part forming a first build-up part and the lower build-up part forming a third build-up part,
wherein the second build-up part is formed such that each of the conductor layers comprises a seed layer formed by electroless plating and an electrolytic plating layer formed below the seed layer and has voids in the seed layer and/or at a boundary portion between the seed layer and the electrolytic plating layer.

13. The printed wiring board according to claim 2, wherein the lower build-up part is formed such that each of the resin insulating layers includes reinforcing material, and the upper build-up part is formed such that each of the first resin insulating layer does not contain reinforcing material.

14. The printed wiring board according to claim 2, wherein the lower build-up part is formed such that a thickness of each of the resin insulating layers is greater than a thickness of each of the resin insulating layers in the upper build-up part and that a thickness of each of the conductor layers is greater than a thickness of each of the conductor layers in the upper build-up part.

15. The printed wiring board according to claim 2, wherein the upper build-up part is formed such that the plurality of resin insulating layers includes an uppermost resin insulating layer formed in contact with the uppermost conductor layer, and the lower build-up part is formed such that the plurality of resin insulating layers includes a lowermost resin insulating layer.

16. The printed wiring board according to claim 2, further comprising:
a bump formed on the electrode in the uppermost conductor layer.

17. The printed wiring board according to claim 16, wherein the bump comprises solder or plating.

18. The printed wiring board according to claim 4, further comprising:
a second build-up part comprising a plurality of resin insulating layers and a plurality of conductor layers and formed between the upper build-up part forming a first build-up part and the lower build-up part forming a third build-up part,
wherein the second build-up part is formed such that each of the conductor layers comprises a seed layer formed by electroless plating and an electrolytic plating layer formed below the seed layer and has voids in the seed layer and/or at a boundary portion between the seed layer and the electrolytic plating layer.

19. The printed wiring board according to claim 4, wherein the lower build-up part is formed such that each of the resin insulating layers includes reinforcing material, and the upper build-up part is formed such that each of the first resin insulating layer does not contain reinforcing material.

20. The printed wiring board according to claim 4, wherein the lower build-up part is formed such that a thickness of each of the resin insulating layers is greater than a thickness of each of the resin insulating layers in the upper build-up part and that a thickness of each of the conductor layers is greater than a thickness of each of the conductor layers in the upper build-up part.
